(19) United States
(12) Patent Application Publication
(10) Pub. No.: US 2026/0196997 A1
(43) Pub. Date: Jul. 9, 2026

(54) GROUND LOSS DETECTION AND OUTPUT CHANNEL DISABLEMENT

(71) Applicant: TEXAS INSTRUMENTS INCORPORATED, Dallas, TX (US)

(72) Inventors: Eung Jung Kim, Allen, TX (US); Xiaochun Zhao, Allen, TX (US)

(21) Appl. No.: 19/013,986

(22) Filed: Jan. 8, 2025

(51) Int. Cl. H03K 17/10; B60L 3/00; H03K 19/003

(52) U.S. Cl. CPC H03K 17/102; B60L 3/0023; H03K 19/00315; H03K 2217/0054

(57) ABSTRACT

A circuit includes a digital circuit, a pullup circuit, a first/second pulldown circuits, and a ground loss detection unit (GLDA). The digital circuit generates a control signal for enabling/disabling an output channel based on an input signal. The pullup circuit enables the output channel if the control signal has a first value, by controlling a gate of a switch that couples a power source to the load. The first pulldown circuit disables the output channel if the control signal has a second value, by controlling the gate. The GLDA generates a ground loss triggering signal by comparing a voltage associated with the ground to an auxiliary voltage. A first value indicates loss of ground connection. The second pulldown circuit pulls a gate of the switch to the source of the switch when the ground loss triggering signal has the first value.

### BACKGROUND

Connection to ground may be lost for a number of different reasons. For example, ground connection may be lost due package stress loosening or disconnecting wires. Ground loss may result in the circuitry to be placed in an uncontrollable mode. Traditionally, loss of connection to ground was detected naturally as the voltage on the ground connection increased to higher than the channel enabled input pin. However, the conventional methodology to detect loss of connection to ground does not work in digitally interfaced devices (e.g., serial peripheral interface (SPI)) because the channel enable/disable signal is stored in digital register and that enabling or disabling the channel is not controlled directly by the input/output pin but are rather controlled by the register values from the digital register and a digital value representing a voltage (stored in a digital register) cannot be compared to an analog voltage value of the ground. Moreover, a voltage of the input pin does not have information regarding whether the channel is enabled or not and as such its comparison to the chip ground does reveal whether connection to ground has been lost. As such, conventional methodology to detect loss of connection to ground does not work for digitally interfaced devices.

### SUMMARY

In an example, an apparatus includes a digital circuit, a gate driver, and a ground loss detection unit. The digital circuit is configured to receive a signal from a microcontroller and to generate a control signal. One value for the control signal is indicative of an output channel associated with a load to be enabled and another value for the control signal is indicative of the output channel associated with the load to be disabled. The gate driver is configured to receive the control signal and to enable or disable a switch controlling the output channel responsive to the control signal. The gate driver is configured to enable the output channel to power the load by a power source, e.g., battery, in response to the control signal having the one value. The gate driver is configured to disable the output channel to prevent the load from being powered by the power source in response to the control signal having the another value. The ground loss detection unit is configured to detect a loss of connection to ground by comparing a voltage associated with the ground to an auxiliary voltage. The auxiliary voltage is derived from the power source. The ground loss detection unit is configured to generate a ground loss triggering signal having a first value in response to detecting loss of connection to the ground and having a second value in response to not detecting loss of connection to the ground. The gate driver is configured to receive the ground loss triggering signal having the first value and in response thereto pulls a gate of the switch to a source of the switch.

In one nonlimiting example, the apparatus further includes the switch where the gate of the switch is connected to the gate driver and further connected to the ground loss detection unit. A drain of the switch is connected to the power source and the source of the switch is connected to the output channel and the load. In one example, the gate driver includes a pullup circuit configured to generate a gate signal for the gate of the switch to enable the output channel in response to the control signal having the one value and further in response to absence of the detecting loss of connection to ground. In yet one nonlimiting example, the gate driver includes a first pulldown circuit configured to generate a gate signal for the gate of the switch to disable the output channel in response to the control signal having the another value and further in response to absence of the detecting loss of connection to ground. According to one nonlimiting example, the gate driver further includes a second pulldown circuit configured to receive the ground loss triggering signal having the first value and in response thereto pull the gate of the switch to the source. In yet another nonlimiting example, the apparatus includes a third pulldown circuit powered by a current source, wherein the third pulldown circuit is configured to pull down the gate of the switch to the source to maintain the output channel in a disabled mode after the second pulldown circuit fails to operate properly when a voltage headroom falls below a threshold, wherein a current from the gate to the source of the switch associated with the third pulldown circuit is smaller than a current from the gate to the source of the switch associated with the second pulldown circuit when operating properly. According to some examples, a voltage associated with the ground increases toward a voltage associated with the power source when connection to the ground is lost. The voltage associated with the ground increases toward the voltage associated with the power source, wherein a switch in the ground loss detection unit is enabled after the voltage associated with the ground increases beyond the auxiliary voltage to generate a current, wherein the current is mirrored using a current mirror to generate the ground loss triggering signal having the first value. The apparatus may further include a protection circuit configured to protect the apparatus from the power source when the power source is reversely connecting to the apparatus.

A circuit may include a digital circuit, a pullup circuit, a first pulldown circuit, a second pulldown circuit, and a ground loss detection unit. The digital circuit is configured to receive an input and to generate a control signal for enabling/disabling an output channel associated with a load. The pullup circuit is configured to receive the control signal and to enable the output channel in response to the control signal having a first value by controlling a gate of a switch that controls power being supplied from a power source to the load. The first pulldown circuit is configured to receive the control signal and to disable the output channel in response to the control signal having a second value by controlling the gate of the switch. The ground loss detection unit is configured to detect a loss of connection to a ground by comparing a voltage associated with the ground to an auxiliary voltage, wherein the auxiliary voltage is derived from the power source, wherein the ground loss detection unit is configured to generate a ground loss triggering signal having a first value in response to detecting loss of connection to the ground and having a second value in response to not detecting the loss of connection to the ground. The second pulldown circuit is configured to receive the ground loss triggering signal and in response thereto pulls a gate of the switch to a source of the switch.

According to some examples, the ground loss detection unit is configured to overwrite the control signal that enables the output channel in response to detecting loss of connection to the ground. The pullup circuit, the first pulldown circuit, and the second pulldown circuit are powered by the auxiliary voltage, in some examples. The circuit may further include a third pulldown circuit, wherein the third pulldown circuit is powered independent of the auxiliary voltage, and wherein the third pulldown circuit is configured to pull down the gate of the switch to the source to maintain the output channel in a disabled mode after the second pulldown circuit fails to operate properly when a voltage headroom falls below a threshold and when the loss of connection to the ground is detected, wherein a current from the gate to the source of the switch associated with the third pulldown circuit is smaller than a current from the gate to the source of the switch associated with the second pulldown circuit when operating properly. A voltage associated with the ground increases toward a voltage associated with the power source when connection to the ground is lost. A switch in the ground loss detection unit is enabled after the voltage associated with the ground increases beyond the auxiliary voltage of a high-side switch to generate a current, wherein the current is mirrored using a current mirror to generate the ground loss triggering signal having the first value. The circuit may further include a protection circuit configured to protect a high-side switch from the power source when the power source is reversely connecting to the circuit.

A system includes a power source, a microcontroller, a circuit, and a load. The microcontroller is configured to generate an output signal for enabling/disabling an output channel, wherein the microcontroller is powered by an auxiliary voltage derived from the power source. The circuit is configured to receive the output signal from the microcontroller and further configured to enable/disable the output channel in response thereto. The microcontroller is powered by the auxiliary voltage and the circuit includes a digital circuit, a pullup circuit, a first and a second pulldown circuits, and a ground loss detection unit. The digital circuit is configured to receive the output signal and to generate a control signal for enabling/disabling an output channel associated with a load. The pullup circuit is configured to receive the control signal and to enable the output channel in response to the control signal having a first value by controlling a gate of a switch that controls power being supplied from the power source to the load. The first pulldown circuit is configured to receive the control signal and to disable the output channel in response to the control signal having a second value by controlling the gate of the switch. The ground loss detection unit is configured to detect at loss of connection to a ground by comparing a voltage associated with the ground to an auxiliary voltage, wherein the auxiliary voltage is derived from the power source, wherein the ground loss detection unit is configured to generate a ground loss triggering signal having a first value in response to detecting loss of connection to the ground and having a second value in response to not detecting loss of connection to the ground. The second pulldown circuit is configured to receive the ground loss triggering signal and in response thereto pull a gate of the switch to a source of the switch. The load is coupled to the circuit that is powered by the power source when the output channel is enabled and is unpowered by the power source when the output channel is disabled.

In an example, the ground loss detection unit is configured to overwrite the control signal that enables the output channel in response to detecting the loss of connection to the ground. In one nonlimiting example, the system includes a third pulldown circuit, wherein the third pulldown circuit is powered independent of the auxiliary voltage. The third pulldown circuit is configured to pull down the gate of the switch to the source to maintain the output channel in a disabled mode after the second pulldown circuit fails to operate properly when a voltage headroom falls below a threshold and when the loss of connection to the ground is detected. A current from the gate to the source of the switch associated with the third pulldown circuit is smaller than a current from the gate to the source of the switch associated with the second pulldown circuit when operating properly. According to some examples, a voltage associated with the ground increases toward a voltage associated with the power source when connection to the ground is lost. A switch in the ground loss detection unit is enabled after the voltage associated with the ground increases beyond the auxiliary voltage of the circuit to generate a current, wherein the current is mirrored using a current mirror to generate the ground loss triggering signal having the first value.

### BRIEF DESCRIPTION OF THE DRAWINGS

FIG. 1A is a schematic diagram of a circuit with ground loss detection unit to place the circuit in a controllable mode when connection to ground is lost, in an example.

FIG. 1B is a schematic diagram of a circuit with ground loss detection unit to place the circuit in a controllable mode after connection to ground is lost, in an example.

FIG. 2 is a schematic diagram of a ground loss detection unit, in an example.

FIG. 3A is a schematic diagram of a gate driver, in an example.

FIG. 3B is a schematic diagram of another gate driver, in an example.

FIG. 4 is a schematic diagram of a protection circuit, in an example.

FIG. 5 is a schematic diagram of an electric vehicle system with a circuit with ground loss detection unit to place the circuit in a controllable mode when connection to ground is lost, in an example.

### DETAILED DESCRIPTION

The same reference numbers or other reference designators are used in the drawings to designate the same or similar (either by function and/or structure) features. Before various examples are described in greater detail, it should be understood that the examples are not limiting, as elements in such examples may vary. It should likewise be understood that a particular example described and/or illustrated herein has elements which may be readily separated from the particular example and optionally combined with any of several other examples or substituted for elements in any of several other examples described herein. It should also be understood that the terminology used herein is for the purpose of describing certain concepts, and the terminology is not intended to be limiting. Unless defined otherwise, all technical and scientific terms used herein have the same meaning as commonly understood in the art to which the examples pertain.

A ground loss detection system is used to detect loss of connection to ground in a digitally interfaced device. In one nonlimiting example, the ground loss detection system may generate a ground loss triggering signal having a first value, e.g., value 1, when loss of ground connection is detected and a second value, e.g., value 0, when no loss of ground connection is detected. According to one nonlimiting example, the ground loss triggering signal is generated by comparing a voltage associated with a ground for the chip to the auxiliary supply voltage, e.g., V_{dd}. The auxiliary supply voltage may be the rail voltage derived from a power supply, e.g., battery. The ground loss triggering signal having the first value causes the gate for a switch that controls the output channel to be pulled down, e.g., the gate for the switch pulled down to its source instead of ground, thereby disabling the output channel. As such, the output channel is kept in a controllable mode. For example, when connection to ground is lost, the loss of ground connection is detected, and the register associated with the digital interface device is flipped to enable the gate pull-down and to disable the output channel regardless of whether a microcontroller indicates that the output channel should be enabled or disabled. In other words, the ground loss detection system overwrites the control signal (from the microcontroller or another component) that enables the output channel, in response to detecting loss of connection to the ground.

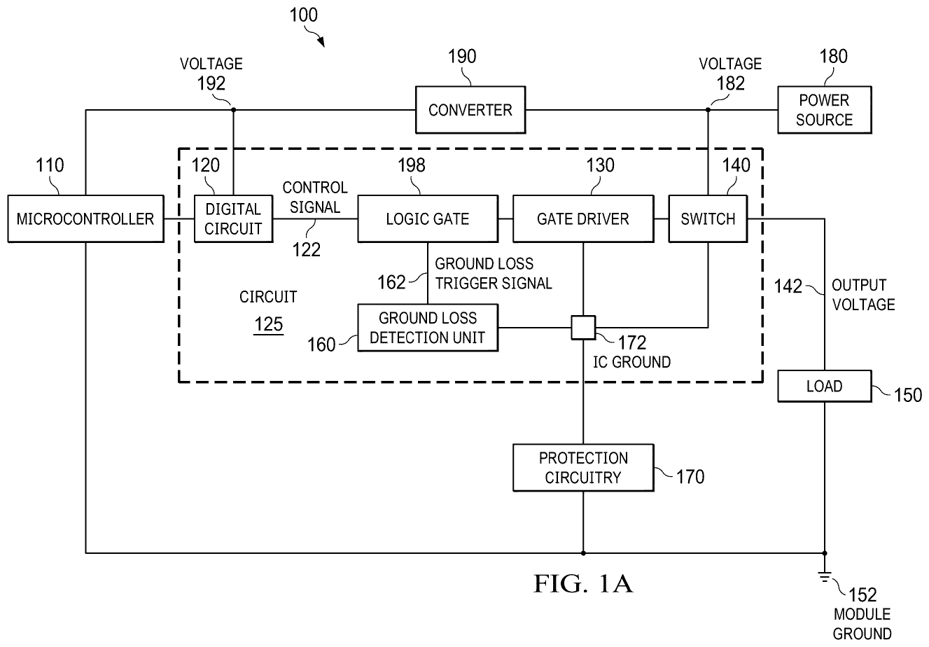

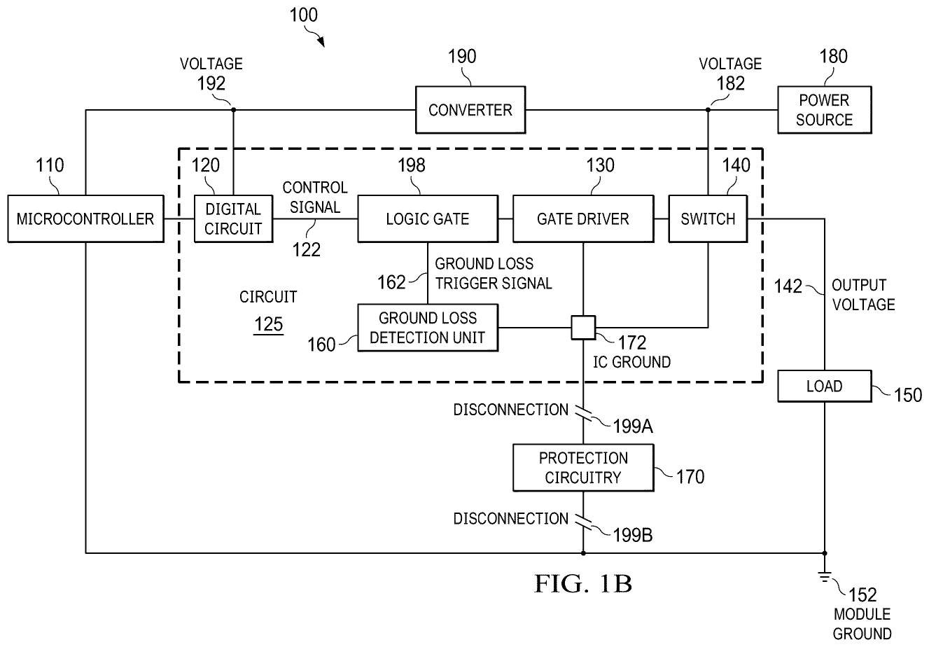

FIG. 1A is a schematic diagram of a circuit with ground loss detection unit to place the circuit in a controllable mode when connection to ground is lost, in an example. System 100 may be a digitally interfaced device. The system 100 may include a power source 180, e.g., a battery, to power a microcontroller 110, a circuit 125 (e.g., a high-side switch that is an integrated solid-state device that combines both the power field-effect transistor (FET) and the gate driver into one device), and a load 150. The power source 180 may supply power to the circuit 125. In one nonlimiting example, the power source 180 supplies voltage 182 to the circuit 125 and may further provide the voltage 182 to a converter 190 to convert the voltage 182 to voltage 192, e.g., auxiliary voltage, for the microcontroller 110 and the circuit 125.

The microcontroller 110 is configured to generate a signal for use by the circuit 125. The circuit 125 in response to the signal from the microcontroller 110 may generate a control signal 122 to enable/disable the output channel, e.g., output voltage 142, for powering the load 150, e.g., motor in an electric vehicle, on/off. The load 150 is connected to the circuit 125 from one side and connected to a module ground 152 connection from another side. In one example, the circuit 125 may couple the power source 180 to the load 150 when the microcontroller 110 sends a signal with one value, e.g., a digital value 11, to indicate that the output channel is to be enabled, e.g., generating output voltage 142 for the load 150. The circuit 125 on the other hand may decouple the power source 180 from the load 150 when the microcontroller 110 sends a signal with another value, e.g., a digital value 01 or 00 as an example, to indicate that the output channel is to be disabled. It is appreciated that the values for enabling/disabling are provided for illustrative purposes and should not be construed as limiting the scope of the examples.

The circuit 125 may include a digital circuit 120, a logic gate 198, a gate driver 130, a switch 140, and a ground loss detection unit 160. In one nonlimiting example, the circuit 125 may be coupled to a protection circuitry 170 to protect the circuit 125 when polarity of the power source 180 is reversed (e.g., when the battery is reversely connected). The protection circuitry 170 may be connected to integrated circuit (IC) ground 172 of the circuit 125 from one side and may be connected to the module ground 152 from another side. In implementations where the protection circuitry 170 is absent, the IC ground 172 becomes the module ground 152 connection.

In one example, the digital circuit 120 receives the signal from the microcontroller 110. The digital circuit 120 may generate a control signal 122 in response to the signal received from the microcontroller 110. For example, the control signal 122 may have one value, e.g., 0 value, to disable the output channel or may have another value, e.g., 1 value, to enable the output channel. The logic gate 198 generates a signal for the gate driver 130 that passes the value of the controls signal 122 to the gate driver 130 in absence of circuit 125 detecting loss of ground connection. The gate driver 130 receives the value associated with the control signal 122 in absence of circuit 125 detecting loss of ground connection and in response thereto controls the switch 140, e.g., pullup, pulldown, etc. For example, the gate driver 130 may pullup the switch 140 (e.g., turn on the switch 140 to couple the voltage 182 to the load 150 for supplying output voltage 142 to the load 150) when the digital circuit 120 generates a control signal 122 with one value, e.g., value 1, in absence of detecting a loss of ground connection, thereby enabling the output channel. The gate driver 130 may pulldown the switch 140 (e.g., turn off the switch 140 to decouple the voltage 182 from the load 150) when the digital circuit 120 generates a control signal 122 with another value, e.g., value 0, in absence of detecting a loss of ground connection, thereby disabling the output channel. Accordingly, the output channel (e.g., output voltage 142 for the load 150) may be controlled using the microcontroller 110.

The circuit 125 may further include a ground loss detection unit 160 to detect when connection to ground is lost. For example, the ground loss detection unit 160 may detect whether the IC ground 172 connection to ground is lost or connection to module ground 152 is lost. The ground loss detection unit 160 may generate a ground loss trigger signal 162 with a first value when loss of ground connection is detected and a second value when no loss of ground connection is detected. The ground loss trigger signal 162 may be logic gated, using logic gate 198, with the control signal 122 to overwrite the value of the control signal 122 when loss of ground connection is detected and to pass the value of the controls signal 122 in absence of detecting loss of ground connection. As such, the ground loss triggering signal 162 may be used to flip the enable register within the circuit 125 in order place the output channel in a controllable mode, e.g., disabled mode, when loss of ground connection is detected. For example, the microcontroller 110 may send a signal indicative of the output channel to be enabled, however, if a loss of ground connection is detected, the enable register is overwritten by the ground loss triggering signal 162 to disable the output channel instead of enabling it as indicated by the microcontroller 110. The operation of the ground loss detection unit 160 when connection to ground is lost is described in FIG. 1B.

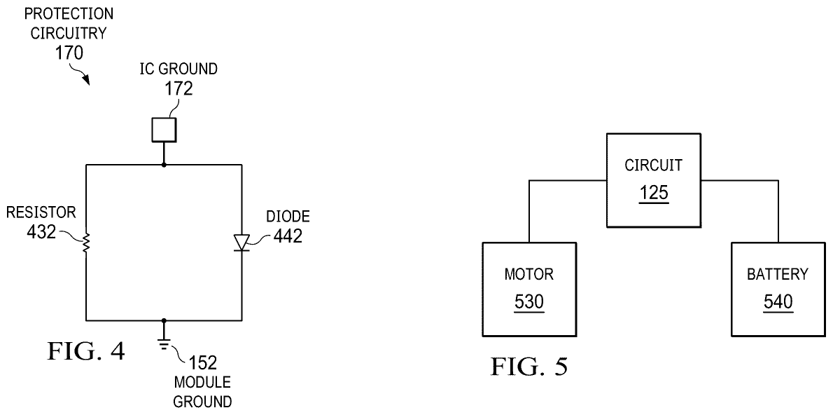

FIG. 1B is a schematic diagram of a circuit with ground loss detection unit to place the circuit in a controllable mode after connection to ground is lost, in an example. In FIG. 1B, disconnection 199A or 199B causes connection to ground to be lost. In a digitally interfaced device, the voltage 192 (e.g., auxiliary voltage ranging between 3-5.5V) is provided to both the microcontroller 110 and the circuit 125. When disconnection 199A or 199B occurs and ground connection is lost, the voltage associated with the IC ground 172 connection floats up close to the voltage 182 (approximately 1-2 V below the voltage from the power source 180 which may range between 6-18 V). The ground loss detection unit 160 is configured to compare the voltage associated with the IC ground 172 connection to the voltage 192 (e.g., auxiliary voltage). Loss of ground connection is detected if the voltage associated with IC ground 172 is greater than the voltage 192 plus an offset voltage (resulting from having the protection circuitry 170 that increases the voltage of IC ground 172 above the module ground 152 connection). In one nonlimiting example, the protection circuitry 170 may include a ground protection diode that increases the voltage by approximately 0.7 V above the module ground 152 connection and is described in more detail in FIG. 4. In one nonlimiting example, the offset voltage is selected to be 2 V to prevent false triggering of loss of ground connection (resulting from ground bouncing) even though the voltage associated with IC ground 172 connection is shifted up by 0.7 associated with the protection circuitry 170. In other words, an additional margin, e.g., 1.3 V, may be added as part of the offset to prevent false triggering of loss of ground connection. In other examples, a different offset voltage may be used, e.g., 3 V. As such, particular values provided herein are for illustration purposes and should not be construed as limiting the scope of the examples. In one nonlimiting example, the offset voltage may be eliminated if the protection circuitry 170 is not present, thereby comparing whether the voltage associated with IC ground 172 is greater than the voltage 192 to detect if connection to ground is lost.

When connection to ground is lost and the voltage of IC ground 172 increases, then pulling the switch 140 to the ground will not disable the output channel because the voltage of IC ground 172 has increased toward voltage 182 resulting from losing the ground connection. Accordingly, the ground loss detection unit 160 generates the ground loss trigger signal 162 with a first value, e.g., value 1, that is logically gated with the control signal 122 to overwrite the value of the controls signal 122 to cause the gate driver 130 to pull down the source of the switch 140 to its gate to make the voltage on gate to source to be approximately 0, thereby disabling the output channel. Thus, the power source 180 is decoupled from powering the load 150. The ground loss trigger signal 162 having the first value indicative of loss of ground connection overwrites any signal from the microcontroller 110. For example, if the microcontroller 110 sends a signal indicative of the output channel to be enabled but if a loss of ground connection is detected, then the ground loss trigger signal 162 overwrites the control signal 122 from the digital circuit 120 generated in response to the signal from the microcontroller 110 and disables the output channel.

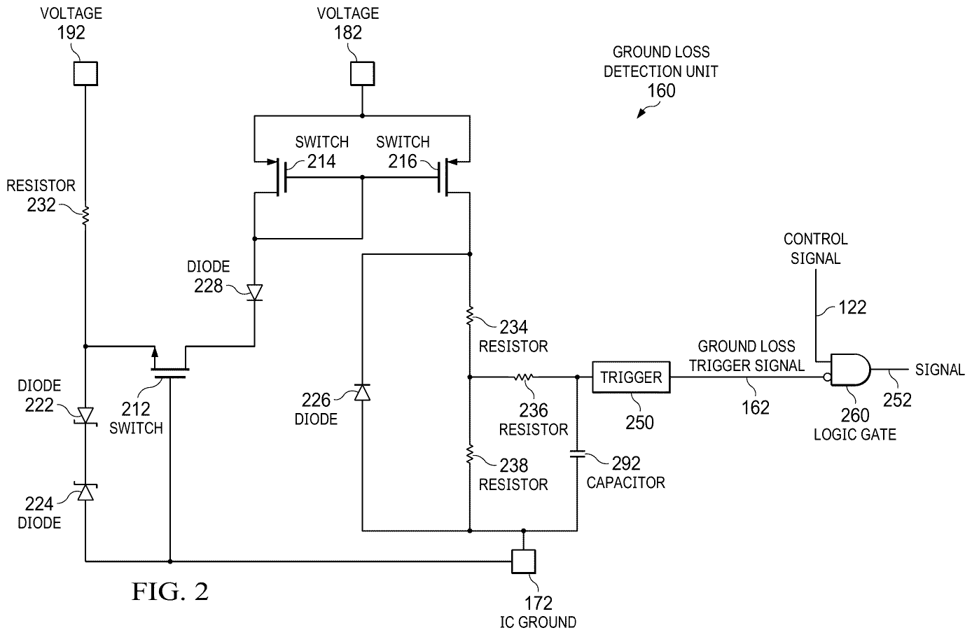

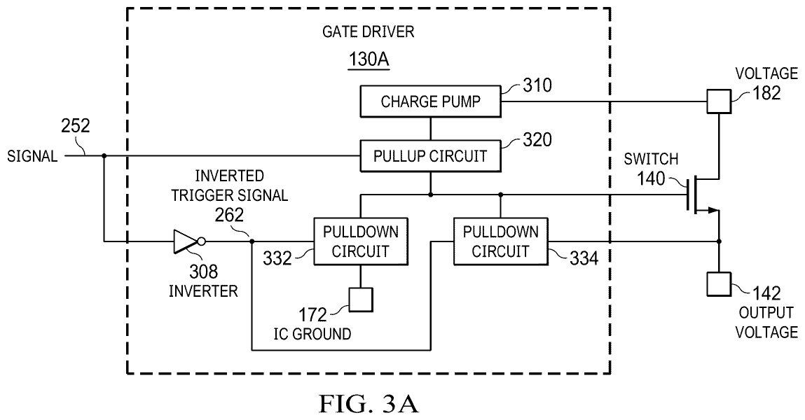

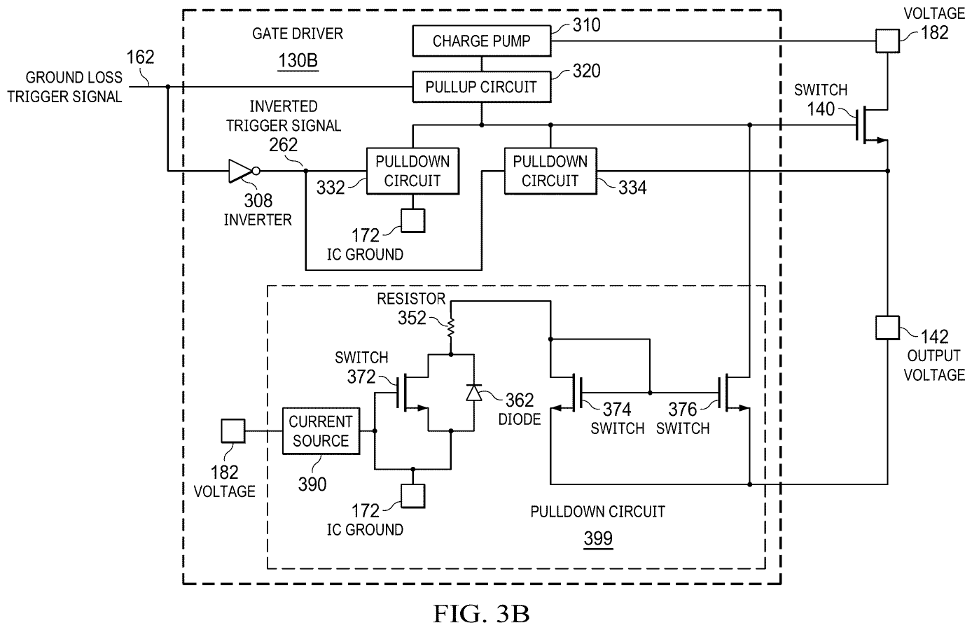

FIG. 2 is a schematic diagram of a ground loss detection unit 160, in an example. The ground loss detection unit 160 may include diodes 222-228, resistors 232-236, switches 212-216, capacitor 292, trigger 250, and a logic gate 260 (similar to logic gate 198). When ground connection is lost, the voltage associated with IC ground 172 increases to a value higher than voltage 192, turning on the switch 212. The switch 212 generates a biased current through the switch 214. The diode 226 may clamp the input voltage to the trigger 250, e.g., Schmitt trigger, and the switch 216 generates a biased current mirroring the current through the switch 214. The current through the switch 216 generates a voltage associated with resistor 238 based on the ratio of resistors 234 and 238. The voltage may be filtered, e.g., low pass filter, using the resistor 236 and the capacitor 292 and transfers a clean signal to the trigger 250. As such, the trigger 250 (buffer with hysteresis) generates the ground loss trigger signal 162 with a first value, e.g., value 1, to indicate that connection to ground has been lost. The ground loss trigger signal 162 may be negated and logically gated 260, e.g., AND gated, with control signal 122 (from the digital circuit 120). As such, regardless of the value associated with the control signal 122 (e.g., indicating whether the output channel to be enabled or disabled), the negated ground loss trigger signal 162 causes the signal 252 to be deasserted to disable the output channel when connection to ground is lost. In other words, the ground loss trigger signal 162 overwrites the control signal 122 generated from the microcontroller 110 attempting to enable the output channel, when the loss of ground connection is detected. In one nonlimiting example, the signal 252 is output from the logic gate 260 to the gate driver 130 and disables the pullup circuit of the gate driver 130 and enables the pulldown circuit of the gate driver 130, described in greater detail in FIGS. 3A-3B, to disable the output channel. In the example of FIG. 2, the diodes 222-224 prevent reverse current from flowing and the diode 228 blocks reverse current from a connection associated with voltage 192 to a connection associated with the voltage 182 when the voltage 182 is less than voltage 192. The specific implementation of the ground loss detection unit 160, as described in FIG. 2, is for illustrative purposes and should not be construed as limiting the scope of the examples.

FIG. 3A is a schematic diagram of a gate driver, in an example. The gate driver 130A (may operate similar to that of 130 described in FIGS. 1A-1B) may include a charge pump 310, a pullup circuit 320, and pulldown circuits 332 and 334. The gate driver 130A receives the signal 252. The signal 252 may have a value associated with loss of ground connection and may have a different value when connection to ground is not lost and not detected.

If the signal 252 is indicative of no loss of ground connection, then the control signal 122 generated by digital circuit 120 controls the operation of the gate driver 130A (similar to that of FIGS. 1A-1B). For example, if the microcontroller 110 is enabling the output channel, then the signal 252 may cause the pullup circuit 320 to cause the switch 140 to be turned on (by controlling the gate of the switch 140 and by pulling it to the charge pump 310), thereby coupling the voltage 182 of the power source 180 to power the load 150 to put the output voltage 142 for the load 150. In contrast, if the microcontroller 110 is disabling the output channel, then the signal 252 may cause the pulldown circuit 332 to cause the switch 140 to be turned off (by pulling down the gate of the switch 140 to IC ground 172), thereby decoupling the voltage 182 of the power source 180 from powering the load 150, thereby disabling the output channel, e.g., pulling down the output voltage 142).

In contrast, if the signal 252 is indicative of detection of loss of ground connection, then the control signal 122 generated by the digital circuit 120 is no longer controlling the operation of the gate driver 130A. Instead, the ground loss trigger signal 162 controls the operation of the gate driver 130A. The signal 252 may have a value 0 to disable the pullup circuit 320. The signal 252 may be inverted using the inverter 308 to generate the inverted trigger signal 262 to enable the pulldown circuits 352-354. As described above, when connection to ground is lost, the voltage on IC ground 172 increases toward voltage 182. Accordingly, the pulldown circuit 332 does not disable the output channel. Instead, the pulldown circuit 334 receives the inverted trigger signal 262 that enables the pulldown circuit 334. The pulldown circuit 334 pulls the gate of the switch 140 to its source, thereby disabling the output channel to keep the output channel in a controllable mode.

FIG. 3B is a schematic diagram of another gate driver, in an example. FIG. 3B is similar to FIG. 3A with additional components. As the voltage associated with IC ground 172 increases to a threshold value, the pulldown circuits 332-334 will stop operating properly due to voltage headroom falling below a threshold. In order to maintain the output channel in the controllable mode, e.g., disabled mode, a different circuitry (a third pulldown circuit 399) is used that is unaffected by the voltage headroom. The third pulldown circuit 399 includes a current source 390, switches 272-376, diode 362 and a resistor 352. The current source 390 uses the voltage 182 of the power source 180 to generate current for the switches 372-374, the diode 362, and the resistor 352 that is mirrored by the switch 376. The switches 372-376, the diode 362 and the resistor 352 generate a small current (order of microamps) from the gate of the switch 140 to its source. The small current being generated is negligible in comparison to the current being generated by the pulldown circuit 334 when operating properly (order of milliamps). However, the small current being generated becomes significant once the pulldown circuit 334 stops operating properly (therefore failing to pulldown the gate of the switch 140 to its source) due to voltage headroom falling below a threshold. As such, the small current pulls the gate of the switch 140 to its source to maintain the output channel in the disabled mode even after the pulldown circuit 334 stops operating properly. In other words, the third pulldown circuit 399 weakly pulls down the gate of the switch 140 to its source that is always pulling the gate to the source (that is negligible when the pulldown circuit 334 is operating properly but significant when the pulldown circuit 334 is not operating properly) even if the supply rail is lost or turned off due to the voltage headroom.

Accordingly, when the connection to ground loss is detected, initially the pulldown circuit 334 becomes enabled to pulls the gate of the switch 140 to its source. However, after a certain period of time, as the voltage of the IC ground 172 increases, the voltage headroom falls below a threshold causing the pulldown circuit 334 to not function properly. As such, the third pulldown circuit 399 that always pulls the gate of the switch 140 to its source (but weakly) becomes significant in absence of the pulldown circuit 334 working properly, thereby maintaining the output channel in a controllable mode, e.g., disabled mode.

Disabling the output channel according to the examples in FIGS. 1A-3B, results in the switch 140 gate to properly discharge its source to cause the voltage on its gate to source to be less than a threshold voltage.

FIG. 4 is a schematic diagram of a protection circuit 170, in an example. The protection circuit 170 may include a diode 442 and a resistor 432 that are in parallel with one another. One side may be connected to the module ground 152 and another side may be connected to IC ground 172. The protection circuit 170 may be a ground protection diode that increases the voltage of IC ground 172 by about 0.7 V above the module ground 152. The protection circuit 170 may protect the high-side switch 125 from events such as power source being reversely connected to the circuit.

FIG. 5 is a schematic diagram of an electric vehicle system with ground loss detection circuit, in an example. A battery 540 may be an electric storage, similar to battery 180, that supplies power to the circuit 125, e.g., high-side switch, to power the motor 530. The circuit 125 may be high-side switches in power distribution module in zonal controlled automotive power architecture that is protected against ground loss fault condition.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

Modifications are possible in the described embodiments, and other embodiments are possible, within the scope of the claims.

What is claimed is:

1. An apparatus comprising:
a digital circuit configured to receive a signal from a microcontroller and to generate a control signal, wherein one value for the control signal is indicative of an output channel associated with a load to be enabled and another value for the control signal is indicative of the output channel associated with the load to be disabled;
a gate driver configured to receive the control signal and to enable or disable a switch controlling the output channel responsive to the control signal, wherein the gate driver is configured to enable the output channel to power the load by a power source in response to the control signal having the one value and wherein the gate driver is configured to disable the output channel to prevent the load from being powered by the power source in response to the control signal having the another value; and
a ground loss detection unit configured to detect a loss of connection to ground by comparing a voltage associated with the ground to an auxiliary voltage, wherein the auxiliary voltage is derived from the power source, wherein the ground loss detection unit is configured to generate a ground loss triggering signal having a first value in response to detecting loss of connection to the ground and having a second value in response to not detecting loss of connection to the ground,
wherein the gate driver is configured to receive the ground loss triggering signal with the first value and in response thereto pulls a gate of the switch to a source of the switch.

2. The apparatus of claim 1 further comprising the switch wherein the gate of the switch is connected to the gate driver and further connected to the ground loss detection unit, and wherein a drain of the switch is connected to the power source, and wherein the source of the switch is connected to the output channel and the load.

3. The apparatus of claim 1, wherein the gate driver includes a pullup circuit configured to generate a gate signal for the gate of the switch to enable the output channel in response to the control signal having the one value and further in response to the ground loss triggering signal having the second value.

4. The apparatus of claim 1, wherein the gate driver includes a first pulldown circuit configured to generate a gate signal for the gate of the switch to disable the output channel in response to the control signal having the another value and further in response to the ground loss triggering signal having the first value.

5. The apparatus of claim 4, wherein the gate driver further includes a second pulldown circuit configured to receive the ground loss triggering signal having the first value and in response thereto pull the gate of the switch to the source.

6. The apparatus of claim 5 further comprising a third pulldown circuit powered by a current source, wherein the third pulldown circuit is configured to pull down the gate of the switch to the source to maintain the output channel in a disabled mode after the second pulldown circuit fails to operate properly when a voltage headroom falls below a threshold, wherein a current from the gate to the source of the switch associated with the third pulldown circuit is smaller than a current from the gate to the source of the switch associated with the second pulldown circuit when operating properly.

7. The apparatus of claim 1, wherein a voltage associated with the ground increases toward a voltage associated with the power source when connection to the ground is lost.

8. The apparatus of claim 7, wherein the voltage associated with the ground increases toward the voltage associated with the power source, wherein a switch in the ground loss detection unit is enabled after the voltage associated with the ground increases beyond the auxiliary voltage to generate a current, wherein the current is mirrored using a current mirror to generate the ground loss triggering signal.

9. The apparatus of claim 1 further comprising a protection circuit configured to protect the apparatus from the power source when the power source is reversely connecting to the apparatus.

10. The apparatus of claim 1, wherein the power source is a battery.

11. A circuit comprising:
a digital circuit configured to receive an input signal and to generate a control signal for enabling/disabling an output channel associated with a load;
a pullup circuit configured to receive the control signal and to enable the output channel in response to the control signal having a first value by controlling a gate of a switch that controls power being supplied from a power source to the load;
a first pulldown circuit configured to receive the control signal and to disable the output channel in response to the control signal having a second value by controlling the gate of the switch;
a ground loss detection unit configured to detect a loss of connection to a ground by comparing a voltage associated with the ground to an auxiliary voltage, wherein the auxiliary voltage is derived from the power source, wherein the ground loss detection unit is configured to generate a ground loss triggering signal having a first value in response to detecting loss of connection to the ground and having a second value in response to not detecting the loss of connection to the ground; and
a second pulldown circuit configured to receive the ground loss triggering signal having the first value and in response thereto pull a gate of the switch to a source of the switch.

12. The circuit of claim 11, wherein the ground loss detection unit is configured to overwrite the control signal that enables the output channel in response to detecting loss of connection to the ground.

13. The circuit of claim 11, wherein the pullup circuit, the first pulldown circuit, and the second pulldown circuit are powered by the auxiliary voltage.

14. The circuit of claim 13 further comprising a third pulldown circuit, wherein the third pulldown circuit is powered independent of the auxiliary voltage, and wherein the third pulldown circuit is configured to pull down the gate of the switch to the source to maintain the output channel in a disabled mode after the second pulldown circuit fails to operate properly when a voltage headroom falls below a threshold and when the loss of connection to the ground is detected, wherein a current from the gate to the source of the switch associated with the third pulldown circuit is smaller than a current from the gate to the source of the switch associated with the second pulldown circuit when operating properly.

15. The circuit of claim 11, wherein a voltage associated with the ground increases toward a voltage associated with the power source when connection to the ground is lost.

16. The circuit of claim 15, wherein a switch in the ground loss detection unit is enabled after the voltage associated with the ground increases beyond the auxiliary voltage of a high-side switch to generate a current, wherein the current is mirrored using a current mirror to generate the ground loss triggering signal.

17. The circuit of claim 11 further comprising a protection circuit configured to protect a high-side switch from the power source when the power source is reversely connecting to the circuit.

18. A system comprising:
a power source;
a microcontroller configured to generate an output signal for enabling/disabling an output channel, wherein the microcontroller is powered by an auxiliary voltage derived from the power source;
a circuit configured to receive the output signal from the microcontroller and further configured to enable/disable the output channel in response thereto, wherein the microcontroller is powered by the auxiliary voltage, and wherein the circuit comprises:
a digital circuit configured to receive the output signal and to generate a control signal for enabling/disabling an output channel associated with a load;
a pullup circuit configured to receive the control signal and to enable the output channel in response to the control signal having a first value by controlling a gate of a switch that controls power being supplied from the power source to the load;
a first pulldown circuit configured to receive the control signal and to disable the output channel in response to the control signal having a second value by controlling the gate of the switch;
a ground loss detection unit configured to detect a loss of connection to a ground by comparing a voltage associated with the ground to an auxiliary voltage, wherein the auxiliary voltage is derived from the power source, wherein the ground loss detection unit is configured to generate a ground loss triggering signal having a first value in response to detecting loss of connection to the ground and having a second value in response to not detecting loss of connection to the ground; and
a second pulldown circuit configured to receive the ground loss triggering signal having the first value and in response thereto pull a gate of the switch to a source of the switch; and
the load coupled to the circuit that is powered by the power source when the output channel is enabled and is unpowered by the power source when the output channel is disabled.

19. The system of claim 18, wherein the ground loss detection unit is configured to overwrite the control signal that enables the output channel in response to detecting the loss of connection to the ground.

20. The system of claim 18 further comprising a third pulldown circuit, wherein the third pulldown circuit is powered independent of the auxiliary voltage, and wherein the third pulldown circuit is configured to pull down the gate of the switch to the source to maintain the output channel in a disabled mode after the second pulldown circuit fails to operate properly when a voltage headroom falls below a threshold and when the loss of connection to the ground is detected, wherein a current from the gate to the source of the switch associated with the third pulldown circuit is smaller than a current from the gate to the source of the switch associated with the second pulldown circuit when operating properly.

21. The system of claim 18, wherein a voltage associated with the ground increases toward a voltage associated with the power source when connection to the ground is lost.

22. The system of claim 21, wherein a switch in the ground loss detection unit is enabled after the voltage associated with the ground increases beyond the auxiliary voltage of the circuit to generate a current, wherein the current is mirrored using a current mirror to generate the ground loss triggering signal.
